(19) United States
(12) Patent Application Publication
(10) Pub. No.: US 2025/0221245 A1
(43) Pub. Date: Jul. 3, 2025

(54) DISPLAY APPARATUS

(71) Applicant: Samsung Display Co., Ltd., Yongin-si (KR)

(72) Inventors: Junhee Bae, Yongin-si (KR); Beomgyu Choi, Yongin-si (KR); Seungpyo Hong, Yongin-si (KR)

(73) Assignee: Samsung Display Co., Ltd., Yongin-si (KR)

(21) Appl. No.: 18/770,001

(22) Filed: Jul. 11, 2024

(30) Foreign Application Priority Data
Dec. 27, 2023 (KR) 10-2023-0193391

(51) Int. Cl. H10K 59/80

(52) U.S. Cl. CPC H10K 59/871

(57) ABSTRACT

A display apparatus with a reduced defect during a manufacturing process includes a cover window including a base portion, an edge portion protruding from a virtual plane on which the base portion is located at an edge of the base portion, and an adhesive layer coupling the base portion to the edge portion, and a display panel disposed under the base portion. The base portion includes a main portion and a protrusion protruding towards the edge portion from the main portion, and the edge portion includes a lateral wall portion and a binding portion protruding towards the base portion from the lateral wall portion.

### CROSS-REFERENCE TO RELATED APPLICATION(S)

This application claims priority to and benefits of Korean Patent Application No. 10-2023-0193391 under 35 U.S.C. § 119, filed on Dec. 27, 2023, in the Korean Intellectual Property Office (KIPO), the entire contents of which are incorporated herein by reference.

### BACKGROUND

### 1. Technical Field

Embodiments relate to a display apparatus with a reduced likelihood of defect occurrence during a manufacturing process.

### 2. Description of the Related Art

Generally, display apparatuses such as smartwatches or smartphones include a cover window. The cover window of a display apparatus is configured to protect display elements of a display panel included in the display apparatus from external impacts and block light such that wirings, circuits, or the like of the display panel cannot be viewed from the outside. To improve the strength of the cover window of the display apparatus, the cover window includes sapphire. In addition, to block light such that wirings, circuits, or the like of the display panel cannot be viewed from the outside, a light-blocking layer is formed on a surface of the cover window.

### SUMMARY

However, in a display apparatus according to the related art, during a manufacturing process, a large amount of sapphire should be cut to form a cover window, and various defects occur during a process of cutting the sapphire.

One or more embodiments include a display apparatus with a reduced likelihood of defect occurrence during a manufacturing process. However, such a technical objective is just an example, and the disclosure is not limited thereto.

Additional aspects will be set forth in part in the description which follows and, in part, will be apparent from the description, or may be learned by practice of the embodiments of the disclosure.

According to an embodiment, a display apparatus may include a cover window including a base portion, an edge portion protruding from a virtual plane on which the base portion is located at an edge of the base portion, and an adhesive layer coupling the base portion to the edge portion, and a display panel disposed under the base portion. The base portion may include a main portion and a protrusion protruding toward the edge portion from the main portion, and the edge portion may include a lateral wall portion and a binding portion protruding toward the base portion from the lateral wall portion.

The base portion may include sapphire.

The edge portion may include at least one of black ceramic and black sapphire.

The adhesive layer may include a light-blocking material.

The binding portion may be seated on the protrusion.

The protrusion may be disposed between the binding portion and a portion of the display panel.

A length of the protrusion may be in a range of about 0.5 mm to about 1.0 mm.

A thickness of the protrusion may be less than a thickness of the main portion.

The thickness of the protrusion may be in a range of about 0.1 mm to about 0.25 mm.

The base portion may have a circular shape in a plan view, and the edge portion may have an annular shape in a plan view.

According to an embodiment, a display apparatus may include a cover window including a base portion, an edge portion protruding from a virtual plane on which the base portion is located at an edge of the base portion, and an adhesive layer coupling the base portion to the edge portion, a display panel disposed under the base portion, and a light-blocking layer covering at least a portion of the edge portion.

The base portion may include a main portion and a protrusion protruding toward the edge portion from the main portion, and the edge portion includes a lateral wall portion and a binding portion protruding toward the base portion from the lateral wall portion.

The base portion may include sapphire.

The edge portion may include crystallized glass.

The adhesive layer may include a light-blocking material.

The binding portion may be seated on the protrusion.

The protrusion may be disposed between the binding portion and a portion of the display panel.

A length of the protrusion may be in a range of about 0.5 mm to about 1.0 mm.

A thickness of the protrusion may be less than a thickness of the main portion.

The thickness of the protrusion may be in a range of about 0.1 mm to about 0.25 mm.

The base portion may have a circular shape in a plan view, and the edge portion may have an annular shape in a plan view.

These and/or other aspects will become apparent and more readily appreciated from the following description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a schematic cross-sectional view of a display apparatus according to an embodiment;

FIG. 3 is a schematic cross-sectional view of a display apparatus of FIG. 1, taken along line A-A′ of FIG. 1;

FIG. 4 is a schematic plan view of a cover window included in a display apparatus according to an embodiment;

FIG. 5 is a schematic cross-sectional view of region B of FIG. 3;

FIG. 6 is a graph showing a degree of refraction visibility according to a thickness of a protrusion;

FIG. 7 is a schematic diagram of an equivalent circuit of a pixel included in the display panel of FIG. 2;

FIG. 8 is a schematic cross-sectional view of the inside of a panel display area of a display panel included in a display apparatus according to an embodiment; and

FIG. 9 is a schematic cross-sectional view of a display apparatus according to another embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

In the specification, “A and/or B” means A or B, or A and B. In the specification, “at least one of A and B” means A or B, or A and B.

In the specification, when various elements such as a layer, a region, a plate, and the like are disposed “on” another element, not only the elements may be disposed “directly on” the other element, but another element may be disposed therebetween.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween. Also, when an element is referred to as being “in contact” or “contacted” or the like to another element, the element may be in “electrical contact” or in “physical contact” with another element; or in “indirect contact” or in “direct contact” with another element.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the case where a certain embodiment may be implemented differently, a specific process order may be performed in the order different from the described order. For example, two processes successively described may be simultaneously performed substantially and performed in the opposite order.

In the specification, “in a plan view” means when an object part is viewed from above. That is, in the specification, “in a plan view” means when viewed in a direction perpendicular to a display panel 10.

Hereinafter, embodiments will be described with reference to the accompanying drawings, wherein like reference numerals refer to like elements throughout and a repeated description thereof is omitted. Sizes of elements in the drawings may be exaggerated or reduced for convenience of explanation. For example, the size and thickness of each element shown in the drawings are arbitrarily represented for convenience of description, and thus, the disclosure is not necessarily limited thereto.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

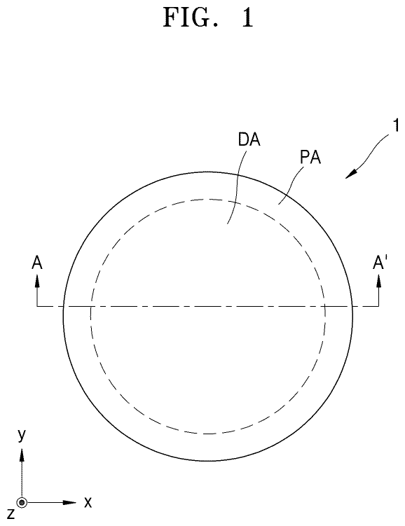

FIG. 1 is a schematic plan view of a display apparatus 1 according to an embodiment. As shown in FIG. 1, the display apparatus 1 may include a display area DA and a peripheral area PA adjacent to the display area DA. The display apparatus 1 may be an apparatus displaying moving images or still images and may be a wearable device such as a smartwatch, watchphone, glasses-type display, or head-mounted display (HMD).

For this purpose, the display apparatus 1 may have a shape suitable for a smartwatch or wearable device. For example, as shown in FIG. 1, the display area DA may have a circular shape in a plan view. In other words, the display area DA may have a circular shape. For example, a planar shape of the display area DA may be a circular shape. However, the disclosure is not limited thereto. The display area DA may have an elliptical shape or a polygonal shape including a quadrangle in a plan view. The display apparatus 1 may be configured to display images through an array of multiple pixels arranged two-dimensionally in the display area DA. Each pixel of the display apparatus 1 may be a region that may emit light of a color. The display apparatus 1 may be configured to display images by using light emitted from the pixels. For example, each pixel may be configured to emit red, green, or blue light.

The peripheral area PA may be arranged outside the display area DA. For example, the peripheral area PA may surround the display area DA. For example, as shown in FIG. 1, the peripheral area PA may have an annular shape in a plan view. The pixel may not be arranged in the peripheral area PA. For example, the peripheral area PA may be a region in which images are not displayed. A driving circuit configured to provide electrical signals to a display element corresponding to a pixel may be arranged in the peripheral area PA. A power line configured to provide power to the display element corresponding to the pixel may be arranged in the peripheral area PA.

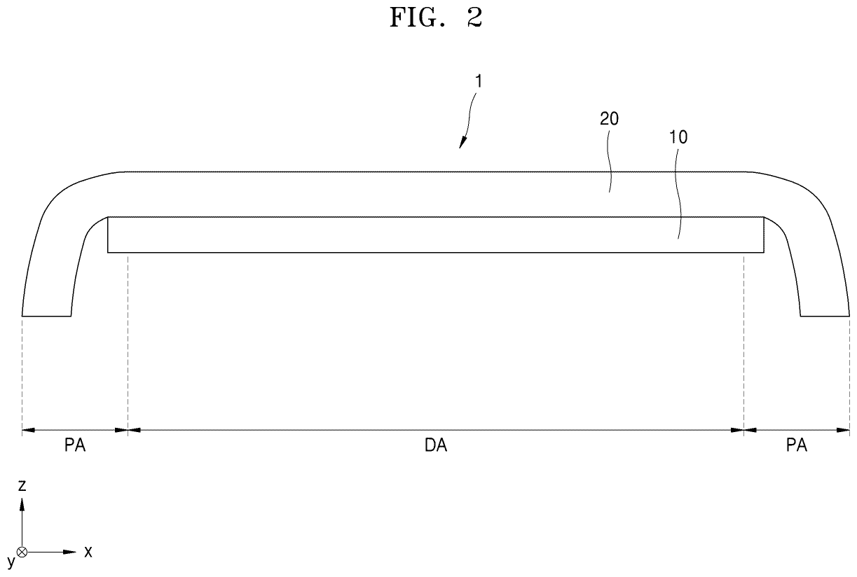

FIG. 2 is a schematic cross-sectional view of the display apparatus 1 according to an embodiment. As shown in FIG. 2, the display apparatus 1 may include a display panel 10 and a cover window 20. In an embodiment, the display apparatus 1 may further include various elements other than the elements shown in FIG. 2.

The display panel 10 may be disposed under the cover window 20. The display panel 10 may be configured to display images. For example, it may be understood that images displayed by the display apparatus 1 are implemented by the display panel 10. The display panel 10 may include multiple display elements, and each of the display elements may be configured to emit red, green, or blue light. Accordingly, the display panel 10 may be configured to display images using light emitted from the display elements. Images displayed by the display panel 10 may be provided to a user through the transparent cover window 20.

The cover window 20 may be disposed on the upper surface (in a +z direction) of the display panel 10. The ‘upper surface’ of the display panel 10 may be defined as a surface facing a direction in which the display panel 10 is configured to display images. In an embodiment, the cover window 20 may cover the upper surface of the display panel 10. The cover window 20 may be configured to protect the upper surface of the display panel 10. Because the cover window 20 forms the appearance of the display apparatus 1, the cover window may include a plane and a curved surface corresponding to the shape of the display apparatus 1. The cover window 20 may have a high transmittance to transmit light emitted from the display panel 10, and have a thin thickness to reduce the weight of the display apparatus 1. The cover window 20 may have high strength and hardness to protect the display panel 10 from external impacts.

Although not shown, an adhesive member may be disposed between the cover window 20 and the display panel 10. The cover window 20 may be attached to the display panel 10 using the adhesive member. The adhesive member disposed between the cover window 20 and the display panel 10 may include at least one of an optical clear resin (OCR), an optical clear adhesive (OCA), and a pressure sensitive adhesive (PSA).

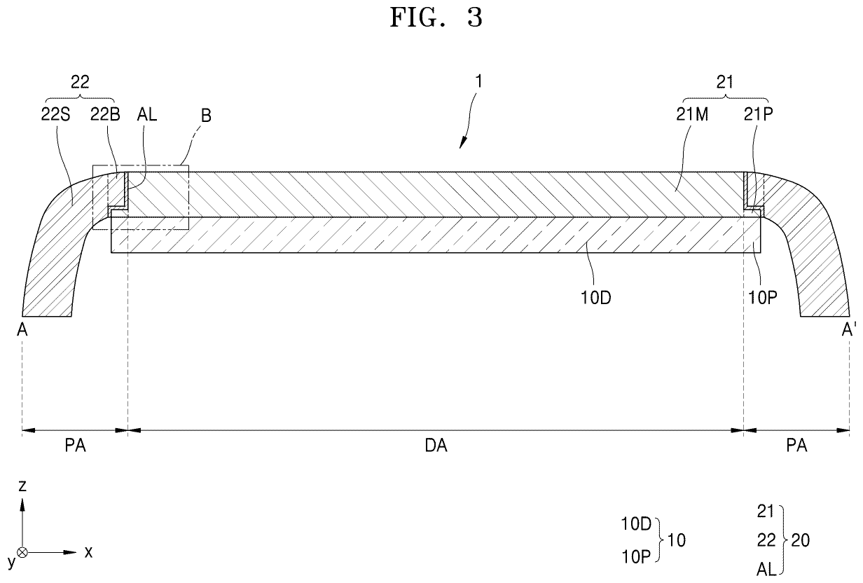

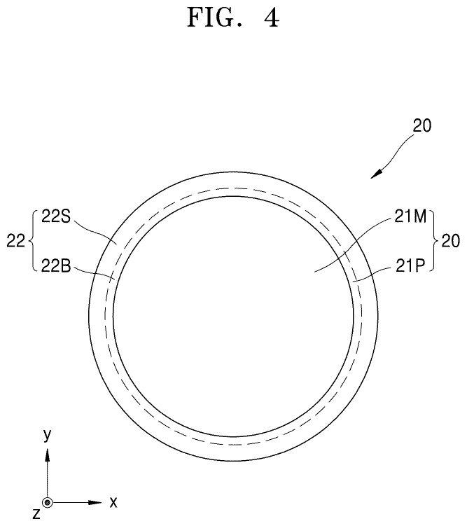

FIG. 3 is a schematic cross-sectional view of the display apparatus 1 of FIG. 1, taken along line A-A′ of FIG. 1. FIG. 4 is a schematic plan view of the cover window 20 included in the display apparatus 1 according to an embodiment. In FIG. 4, for convenience of description, illustration of an adhesive layer AL is omitted.

As shown in FIG. 3, the display panel 10 may include a panel display area 10D and a panel peripheral area 10P. The panel display area 10D may have a shape corresponding to the display area DA of the display apparatus 1 in a plan view. For example, the panel display area 10D may have a circular shape in a plan view. However, the disclosure is not limited thereto.

As described above, the display panel 10 may display images, and the panel display area 10D of the display panel 10 may be a region configured to display images. Pixels may be arranged in the panel display area 10D. A pixel may be a minimum unit that implements an image and denotes an emission area. A pixel may be provided in plurality, and each of the pixels may be configured to emit red, green, or blue light using a display element. The display element may be an organic light-emitting diode OLED including an organic emission layer. In another embodiment, the display element may be a light-emitting diode LED including an inorganic emission layer. The size of the light-emitting diode LED may be microscales or nanoscales. For example, the light-emitting diode may be a micro light-emitting diode. In another embodiment, the light-emitting diode may be a nanorod light-emitting diode. The nanorod light-emitting diode may include gallium nitride (GaN). In an embodiment, a color-converting layer may be disposed on the display element, and the color-converting layer may include quantum dots. In another embodiment, the display element may be a quantum-dot light-emitting diode including a quantum-dot emission layer. Hereinafter, for convenience of description, an embodiment that the display element includes an organic light-emitting diode is described.

The panel peripheral area 10P may be arranged adjacent to the panel display area 10D. For example, the panel peripheral area 10P may surround the panel display area 10D in a plan view. For example, the panel peripheral area 10P may have an annular shape in a plan view. However, the disclosure is not limited thereto.

The pixels may not be arranged in the panel peripheral area 10P. For example, the panel peripheral area 10P may be a non-display area in which images are not displayed. A driving circuit configured to provide electrical signals to a display element corresponding to a pixel may be arranged in the panel peripheral area 10P, or a power line configured to provide power to the display element corresponding to the pixel may be arranged in the panel peripheral area 10P. In an embodiment, the driving circuit may be a scan driving circuit configured to provide scan signals to a pixel circuit electrically connected to the display element through a scan line. In an embodiment, the driving circuit may be an emission control driving circuit configured to provide emission control signals to the pixel circuit electrically connected to the display element through an emission control line. In an embodiment, the driving circuit may be a data driving circuit configured to provide data signals to the pixel circuit electrically connected to the display element through a data line. Elements included in the display panel 10 are described below in detail.

As shown in FIG. 3, the cover window 20 may include a base portion 21, an edge portion 22, and the adhesive layer AL. The base portion 21 and the edge portion 22 may form an entire appearance of the cover window 20. For example, as shown in FIG. 4, the base portion 21 may have a circular shape in a plan view, and the edge portion 22 may have an annular shape in a plan view. For example, the edge portion 22 may surround the base portion 21 in a plan view. The adhesive layer AL may be disposed between the base portion 21 and the edge portion 22 to couple the base portion 21 to the edge portion 22.

For example, the base portion 21 may form a central portion of the cover window 20. The base portion 21 may be a flat region. The display apparatus 1 may be configured to display most of images through the base portion 21. In other words, images displayed by the display panel 10 may be provided to a user through the base portion 21 of the cover window 20. For example, the display panel 10 may be disposed under the base portion 21.

The base portion 21 may be transparent. In other words, the base portion 21 may be light-transmissive. The base portion 21 may have excellent hardness. For this purpose, the base portion 21 may include sapphire. Sapphire is a material having an excellent hardness, and a layer including sapphire may have stronger scratch resistance than a layer including glass. For example, a layer including sapphire may have improved scratch resistance than a layer containing glass. Accordingly, the cover window 20 may have strong strength and hardness to protect the display panel 10 from external impacts, and may prevent scratches from occurring on the cover window 20.

The edge portion 22 may be arranged to be adjacent to the edge of the base portion 21. For example, the edge portion 22 may form the lateral surface of the cover window 20. For example, the edge portion 22 may have a curved shape around an axis. Accordingly, the edge portion 22 may have a shape protruding from a virtual first plane on which the base portion 21 is located. For example, the base portion 21 may be located on the virtual first plane approximately parallel to an xy-plane, and the edge portion 22 may have a shape protruding in a direction (a −z direction) perpendicular to the xy-plane from the edge of the base portion 21.

The axis may extend along the circumference of the base portion 21 in a plan view. For example, the edge portion 22 may have a curved shape in a cross-sectional view around the axis extending along the circumference of the base portion 21 in a plan view. Accordingly, the display panel 10 may be located in a space defined by the base portion 21 and the edge portion 22 of the cover window 20. Unlike the transparent base portion 21, the edge portion 22 may be opaque. In other words, the edge portion 22 may be non-transmissive. Accordingly, the edge portion 22 may block light such that wirings, a circuit, or the like of the display panel 10 is not viewed from the outside.

The adhesive layer AL may couple the base portion 21 to the edge portion 22. For example, the adhesive layer AL may be disposed between the base portion 21 and the edge portion 22. The edge portion 22 may be coupled to the edge of the base portion 21 through the adhesive layer AL. For example, the edge portion 22 may not be integrally formed with the base portion 21, and the edge portion 22 may be a separate element from the base portion 21.

Generally, in the case where the cover window 20 is formed such that the edge portion 22 is integrally provided with the base portion 21 including sapphire and has a curved shape around a preset axis, a large amount of sapphire should be cut in the process of forming the curved shape of the edge portion 22. Cutting marks may occur on the cover window 20 due to such cutting, and in the case where sapphire is excessively cut, it may be difficult to manufacture the cover window 20 of a desired size. In the case where residue remains on the cover window 20, the residue may cause appearance defects.

However, the edge portion 22 of the cover window 20 according to an embodiment may be a separate element from the base portion 21 and may be coupled to the base portion 21 through the adhesive layer AL. For example, the cover window 20 may not be formed such that the edge portion 22 is integrally provided with the base portion 21 including sapphire and has a curved shape around a preset axis. Accordingly, defect may be reduced in the process of manufacturing the cover window 20.

In an embodiment, the edge portion 22 may include at least one of black ceramic and black sapphire. For example, the edge portion 22 may include at least one of ceramic and sapphire, and the at least one of the ceramic and the sapphire may be an opaque light-blocking material. For example, the edge portion 22 may include at least one of black ceramic and black sapphire. Accordingly, the edge portion 22 may be opaque. The ceramic may include at least one of alumina, silica, magnesia, zirconia, and mullite. For example, the ceramic may include zirconia. A layer including ceramic may have similar strength and scratch resistance to a layer including sapphire.

In the specification, in case that one element has a black color, it may mean that a light absorption rate of the element in a visible light region is greater than or equal to about 90%. For example, a light absorption rate of black ceramic and black sapphire in the visible light region may be greater than or equal to about 90%. For example, in case that the edge portion 22 includes at least one of black ceramic and black sapphire, a light absorption rate of the edge portion 22 in the visible light region may be greater than or equal to about 90%.

The adhesive layer AL may include at least one of a pressure sensitive adhesion (PSA), an optical clear adhesive (OCA), and an optical clear resin (OCR). In an embodiment, the adhesive layer AL may further include a light-blocking material. For example, the adhesive layer AL may include a black material. The light-blocking material may include at least one of black dye and black particles. In another embodiment, the light-blocking material may include metal particles. The metal particles may be, for example, nickel, aluminum, molybdenum and/or an alloy thereof. In another embodiment, the light-blocking material may include metal oxide particles such as chromium oxide or metal nitride particles such as chromium nitride. For example, the light-blocking material may include at least one of Cr, CrO_{X}, Cr/CrO_{X}, Cr/CrO_{X}/CrN_{Y}, graphite, carbon black, and carbon nanotubes. In another embodiment, the light-blocking material may include a black organic pigment, and the black organic pigment may include at least one of aniline black, lactam black, and perylene black.

The base portion 21 and the edge portion 22 may respectively include a protrusion 21P and a binding portion 22B to improve binding force. For example, the base portion 21 may include a main portion 21M and the protrusion 21P. As described above, images displayed by the display panel 10 may be provided to a user through the base portion 21 of the cover window 20, and the main portion 21M may be a portion of the base portion 21 corresponding to the panel display area 10D of the display panel 10. In other words, the main portion 21M may be a portion of the base portion 21 corresponding to the display area DA of the display apparatus 1. For example, the main portion 21M may be disposed on the panel display area 10D of the display panel 10.

The protrusion 21P may be a portion of the base portion 21 protruding in a direction to the edge portion 22 from the main portion 21M. As shown in FIG. 4, the protrusion 21P may extend along the circumference of the main portion 21M in a plan view. For example, the protrusion 21P may have a shape protruding from the edge of the main portion 21M in directions parallel to an xy-plane. In other words, the protrusion 21P may protrude from a surface of the main portion 21M and extend along the circumference of the main portion 21M. For example, the protrusion 21P may be disposed on the panel peripheral region 10P of the display panel 10.

The edge portion 22 may include a lateral wall portion 22S and the binding portion 22B. As described above, to define a space in which the display panel 10 is to be located, the edge portion 22 may have a curved shape around a preset axis. In other words, the edge portion 22 may form the lateral surface of the cover window 20, and the lateral wall portion 22S may be a portion of the edge portion 22 corresponding to the lateral surface of the cover window 20.

The binding portion 22B may be a portion of the edge portion 22 protruding from the lateral wall portion 22S in a direction to the base portion 21. The binding portion 22B may be a portion corresponding to the protrusion 21P. As shown in FIG. 4, the binding portion 22B may extend along the circumference of the main portion 21M in a plan view. For example, the binding portion 22B may be disposed on the protrusion 21P and have a shape corresponding to the protrusion 21P in a plan view. In other words, the binding portion 22B may be seated on the protrusion 21P.

The main portion 21M and the protrusion 21P may include a same material and be integrally formed, and a surface of the protrusion 21P may extend from a surface of the main portion 21M. For example, the lower surface (in a −z direction) of the protrusion 21P may extend from the lower surface (the −z direction) of the main portion 21M. The lateral wall portion 22S and the binding portion 22B may include a same material and be integrally formed, and a surface of the binding portion 22B may extend from a surface of the lateral wall portion 22S. For example, the upper surface (a +z direction) of the binding portion 22B may extend from the upper surface (the +z direction) of the lateral wall portion 22S. Accordingly, the binding portion 22B may be disposed on the protrusion 21P. For example, because the protrusion 21P is disposed on the panel peripheral area 10P of the display panel 10, and the binding portion 22B is seated on the protrusion 21P, the protrusion 21P may be disposed between a portion of the display panel 10 and the binding portion 22B. Because the binding portion 22B of the edge portion 22 is disposed on the panel peripheral area 10P of the display panel 10, wirings, a circuit, or the like of the panel peripheral area 10P of the display panel 10 may be hidden to be not viewed from the outside.

Generally, because the base portion 21 is transparent by including sapphire, elements disposed under the base portion 21 may be viewed by a user. In the case where the protrusion 21P of the base portion 21 is disposed on the binding portion 22B of the edge portion 22, the binding portion 22B may be viewed by a user through the base portion 21 together with the panel display area 10D of the display panel 10. Because the binding portion 22B and the display panel 10 include different structures and materials, a user feels a sense of difference between the binding portion 22B and the display panel 10. In contrast, in the display apparatus according to an embodiment, because the protrusion 21P of the base portion 21 is disposed under the binding portion 22B of the edge portion 22, the binding portion 22B may not be viewed by a user through the base portion 21. Accordingly, a user may not feel a sense of difference from the binding portion 22B.

Although it is shown in FIG. 3 that both the upper surface (the +z direction) and the lower surface (the −z direction) of the base portion 21 have a flat shape entirely, the disclosure is not limited thereto. For example, the upper surface (the +z direction) of the base portion 21, which is an outer surface of the base portion 21 in a direction opposite to the display panel 10, may generally have a flat shape and locally include a curved portion.

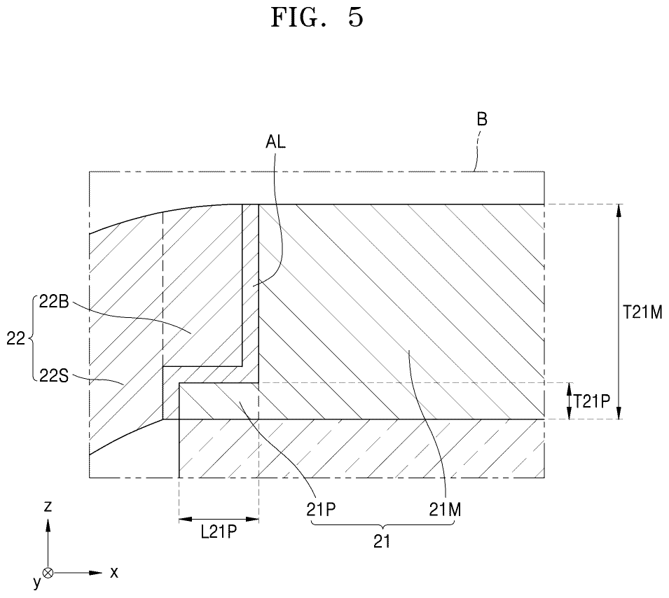

FIG. 5 is a schematic cross-sectional view of region B of FIG. 3. As shown in FIG. 5, the protrusion 21P may protrude from the main portion 21M in a direction to the edge portion 22, and a length L21P of the protrusion 21P may be in a range of about 0.5 mm to about 1.0 mm. In the specification, the length of the protrusion 21P denotes a shortest distance between a side of the protrusion 21P adjacent to the edge portion 22 and another side of the protrusion 21P adjacent to the main portion 21M.

In case that the length L21P of the protrusion 21P is less than 0.5 mm, the surface area of the protrusion 21P that is contact with the binding portion 22B may be small, and binding force between the base portion 21 and the edge portion 22 may be low. In case that a length L21P of the protrusion 21P exceeds 1.0 mm, the impact resistance of the protrusion 21P may be poor, and the strength of the cover window 20 may be low.

A thickness T21P of the protrusion 21P may be less than a thickness T21M of the main portion 21M. For example, the thickness T21P of the protrusion 21P may be about 18% or less of the thickness T21M of the main portion 21M. For example, in case that the thickness T21M of the main portion 21M is about 1.5 mm, the thickness T21P of the protrusion 21P may be in a range of about 0.1 mm to about 0.25 mm. In the specification, the thickness of the protrusion 21P denotes a shortest distance between a side of the protrusion 21P in a direction (the −z direction) to the display panel 10 and another side of the protrusion 21P in the opposite direction (the +z direction) of the display panel 10. In the specification, the thickness of the main portion 21M denotes a shortest distance between a side of the main portion 21M in a direction (the −z direction) to the display panel 10 and another side of the main portion 21M in the opposite direction (the +z direction) of the display panel 10.

In case that a thickness T21P of the protrusion 21P is less than 0.1 mm, the impact resistance of the protrusion 21P may be poor, and the strength of the cover window 20 may be low. In case that the thickness of the protrusion 21P exceeds 0.25 mm, a refraction visibility degree of the display apparatus 1 may be excessively large.

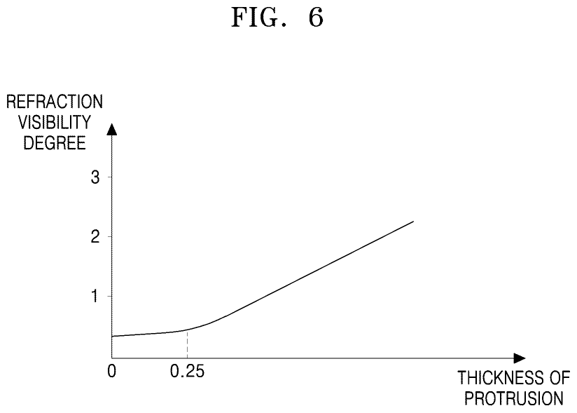

FIG. 6 is a graph showing a degree of refraction visibility according to the thickness of the protrusion T21P. A horizontal axis of the graph of FIG. 6 represents the thickness T21P of the protrusion 21P, and the unit is millimeters. A vertical axis of the graph of FIG. 6 represents a refraction visibility degree, which is a relative value.

Generally, a portion of light emitted from the display panel 10 may be emitted in a direction oblique to the upper surface (the +z direction) of the display panel 10. In case that a portion of light emitted from a portion of the display panel 10 adjacent to the protrusion 21P is emitted in a direction oblique to the upper surface (the +z direction) of the display panel 10, a portion of the light may be refracted at the interface between the protrusion 21P and the display panel 10. In the specification, the refraction visibility degree denotes a degree in which a portion of light emitted from the display panel 10 is refracted at the interface between the protrusion 21P and the display panel 10 and visible to a user.

In case that the thickness T21P of the protrusion 21P is small, because light refracted at the interface between the protrusion 21P and the display panel 10 is hidden by the edge portion 22 before reaching the upper surface of the main portion 21M, a degree to which the light is visible to the user is small. However, in case that the thickness T21P of the protrusion 21P is large, because light refracted at the interface between the protrusion 21P and the display panel 10 is not sufficiently hidden by the edge portion 22 before reaching the upper surface of the main portion 21M, a degree to which the light is visible to the user is large. As shown in FIG. 6, in case that the thickness T21P of the protrusion 21P exceeds 0.25 mm, a refraction visibility degree of the display apparatus 1 is excessively large. Accordingly, the thickness T21P of the protrusion 21P may be in a range of about 0.1 mm to about 0.25 mm.

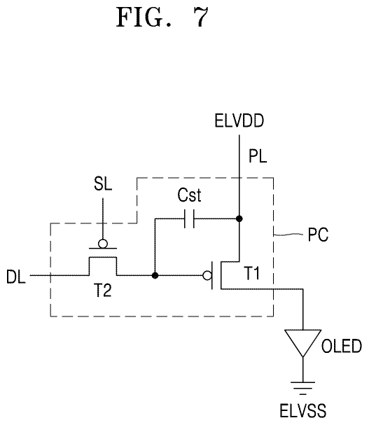

FIG. 7 is a schematic diagram of an equivalent circuit of a pixel circuit PC included in the display panel 10 of FIG. 2. The pixel circuit PC may be electrically connected to a display element, and one display element may correspond to one pixel. FIG. 7 shows an organic light-emitting diode OLED as a display element. In an embodiment, the display element may be configured to emit red, green, or blue light.

The pixel circuit PC may include a first transistor T1, a second transistor T2, and a storage capacitor Cst. The second transistor T2 may be a switching thin-film transistor, may be connected to a scan line SL and a data line DL and configured to be turned on according to a switching signal and transfer a data signal to the first transistor T1, the data signal being input from the data line DL, and the switching signal being input from the scan line SL. The storage capacitor Cst may include an end electrically connected to the second transistor T2, and another end electrically connected to a driving voltage line PL. The storage capacitor Cst may be configured to store a voltage corresponding to a difference between a voltage transferred from the second transistor T2 and the driving voltage ELVDD supplied from the driving voltage line PL.

The first transistor T1 may be a driving transistor, may be connected to the driving voltage line PL and the storage capacitor Cst, and configured to control the magnitude of a driving current according to the voltage stored in the storage capacitor Cst, the driving current flowing from the driving voltage line PL to the organic light-emitting diode OLED. The organic light-emitting diode OLED may be configured to emit light having a brightness corresponding to the driving current. An opposite electrode of the organic light-emitting diode OLED may be configured to receive an electrode voltage ELVSS.

Although it is described with reference to FIG. 7 that the pixel circuit PC includes two transistors and one storage capacitor, the disclosure is not limited thereto. For example, the number of transistors and the number of storage capacitors may be variously changed according to the design of the pixel circuit PC. Although FIG. 7 shows all of the transistors are P-type transistors, the disclosure is not limited thereto. For example, some of the transistors may be N-type transistors. For example, all of the transistors may be N-type transistors.

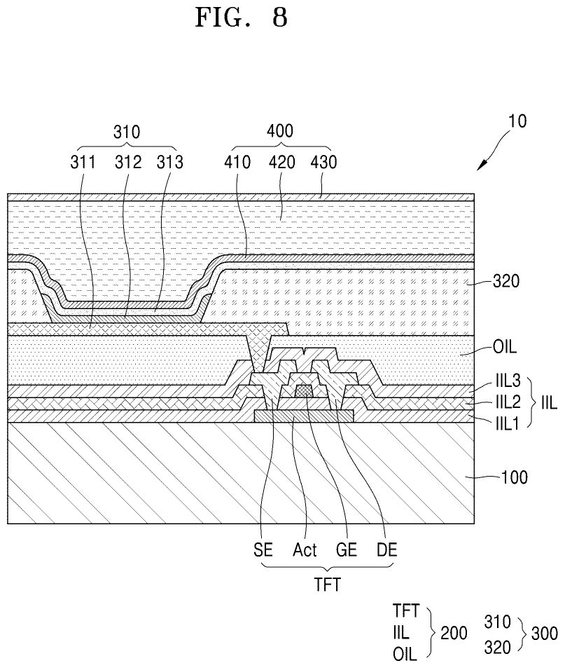

FIG. 8 is a schematic cross-sectional view of the inside of the panel display area 10D of the display panel 10 included in the display apparatus 1 according to an embodiment. As recognized by those of ordinary skill in the art, the display panel 10 may further include various elements other than the elements shown in FIG. 8.

Referring to FIG. 8, the display panel 10 may include a substrate 100 and a transistor and a light-emitting element formed by various layers formed on the substrate 100. For example, the display panel 10 may include the substrate 100, a pixel circuit layer 200, a display element layer 300, and an encapsulation layer 400.

The substrate 100 may include glass, metal, or a polymer resin. The substrate 100 may be flexible or bendable. The substrate 100 may include a polymer resin including at least one of polyethersulphone, polyacrylate, polyetherimide, polyethylene naphthalate, polyethylene terephthalate, polyphenylene sulfide, polyarylate, polyimide, polycarbonate, and cellulose acetate propionate. The substrate 100 may have a multi-layered structure including two layers each including a polymer resin, and a barrier layer including an inorganic material (such as silicon oxide (SiO_{X}), silicon nitride (SiN_{X}), silicon oxynitride (SiO_{X}N_{Y}), and the like) between the two layers. However, the disclosure is not limited thereto, and various modifications may be made.

The pixel circuit layer 200 may be disposed on the substrate 100. The pixel circuit layer 200 may include a transistor TFT, an inorganic insulating layer IIL, and an organic insulating layer OIL. The transistor TFT may include a semiconductor layer Act, a gate electrode GE, a source electrode SE, and a drain electrode DE. The inorganic insulating layer IIL may include a gate insulating layer IIL1, a first interlayer insulating layer IIL2, and a second interlayer insulating layer IIL3. For convenience of illustration, FIG. 8 shows one transistor TFT. The transistor TFT may correspond to the first transistor T1.

The semiconductor layer Act may be disposed on the substrate 100. The semiconductor layer Act may include polycrystalline silicon. In another embodiment, the semiconductor layer Act may include amorphous silicon, an oxide semiconductor, or an organic semiconductor. In an embodiment, the semiconductor layer Act may include a channel region, a drain region, and a source region, the drain region and the source region being disposed on opposite sides of the channel region.

The gate insulating layer IIL1 may be disposed on the semiconductor layer Act and the substrate 100. The gate insulating layer IIL1 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may include zinc oxide (ZnO) and/or zinc peroxide (ZnO₂).

The gate electrode GE may be disposed on the gate insulating layer IIL1. For example, because the gate insulating layer IIL1 is disposed between the semiconductor layer Act and the gate electrode GE, insulation between the semiconductor layer Act and the gate electrode GE may be secured. The gate electrode GE may overlap the channel region of the semiconductor layer Act in a plan view. The gate electrode GE may include a low-resistance metal material. In an embodiment, the gate electrode GE may include a conductive material such as molybdenum (Mo), aluminum (AI), copper (Cu), and titanium (Ti) and include a single layer or a multi-layer including the conductive material.

The first interlayer insulating layer IIL2 may be disposed on the gate electrode GE and the gate insulating layer IIL1. The first interlayer insulating layer IIL2 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnO_{X}).

The source electrode SE and the drain electrode DE may be disposed on the first interlayer insulating layer IIL2. Each of the source electrode SE and the drain electrode DE may be connected to the semiconductor layer Act through a contact hole formed in the gate insulating layer IIL1 and the first interlayer insulating layer IIL2. At least one of the source electrode SE and the drain electrode DE may include a conductive material such as molybdenum (Mo), aluminum (AI), copper (Cu), and titanium (Ti) and include a single layered or multi-layered structure including the above conductive material. In an embodiment, at least one of the source electrode SE and the drain electrode DE may have a multi-layered structure of Ti/Cu/Ti.

The second interlayer insulating layer IIL3 may be disposed on the source electrode SE, the drain electrode DE, and the first interlayer insulating layer IIL2. The second interlayer insulating layer IIL3 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnO_{X}).

An organic insulating layer OL may be disposed on the second insulating layer IIL3. The organic insulating layer OIL may generally planarize the upper surface of the pixel circuit layer 200. The organic insulating layer OIL may include, for example, an acrylic material, benzocyclobutene (BCB), or hexamethyldisiloxane (HMDSO). Although it is shown in FIG. 8 that the organic insulating layer OL is a single layer, the disclosure is not limited thereto, and the organic insulating layer OL may be a multi-layer. However, various modifications may be made.

The display element layer 300 may be disposed on the pixel circuit layer 200. The display element layer 300 may include a display element 310 and a pixel-defining layer 320. The display element 310 may be electrically connected to the transistor TFT. The display element 310 may be an organic light-emitting diode including a pixel electrode 311, an opposite electrode 313, and an intermediate layer 312, wherein the intermediate layer 312 may be disposed between the pixel electrode 311 and the opposite electrode 313, and may include an emission layer. In case that the display element 310 is electrically connected to the transistor TFT, the pixel electrode 311 of the organic light-emitting diode may be electrically connected to the transistor TFT.

The pixel electrode 311 may be electrically connected to the transistor TFT by being in contact with one of the source electrode SE and the drain electrode DE through a contact hole formed in the second interlayer insulating layer IIL3 and the organic insulating layer OIL. The pixel electrode 311 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 311 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the pixel electrode 311 may further include a layer on/under the reflective layer, the layer including ITO, IZO, ZnO, or In₂O₃.

The pixel-defining layer 320 may cover the edge of the pixel electrode 311. The pixel-defining layer 320 may include a pixel opening, and the pixel opening may overlap the pixel electrode 311 in a plan view. The pixel opening may define an emission area of light emitted from the display element 310. The pixel-defining layer 320 may include an organic insulating material and/or an inorganic insulating material. In an embodiment, the pixel-defining layer 320 may include a light-blocking material.

The intermediate layer 312 may be disposed on the pixel electrode 311 and the pixel-defining layer 320. The intermediate layer 312 may include a low-molecular weight material or a polymer material. In case that the intermediate layer 312 includes a low molecular weight material, the intermediate layer 312 may have a structure in which a hole injection layer (HIL), a hole transport layer (HTL), an emission layer (EML), an electron transport layer (ETL), an electron injection layer (EIL), etc. are stacked in a single or composite configuration. The intermediate layer 312 may be formed by vacuum deposition. In case that the intermediate layer 312 includes a polymer material, the intermediate layer 312 may have a structure including an HTL and an EML, and the HTL may include poly (3, 4-ethylenedioxythiophene) (PEDOT), and the EML may include a polymer material such as a polyphenylene vinylene (PPV)-based material and a polyfluorene-based material. The intermediate layer 312 may be formed by screen printing, inkjet printing, laser induced thermal imaging (LITI), or the like. The intermediate layer 312 is not necessarily limited thereto and may have various structures. In an embodiment, the intermediate layer 312 may include a layer, which is one body over the pixel electrodes 311, or include a layer patterned to correspond to each of the pixel electrodes 311.

The opposite electrode 313 may be disposed on the intermediate layer 312 and the pixel-defining layer 320. The opposite electrode 313 may be integrally formed over multiple pixels to correspond to multiple pixel electrodes 311. The opposite electrode 313 may include a light-transmissive conductive layer including ITO, In₂O₃, or IZO, or include a semi-transmissive layer including a metal such as aluminum (AI) or silver (Ag). For example, the opposite electrode 313 may be a semi-transmissive layer including magnesium (Mg) and silver (Ag).

Because the display element 310 may be readily damaged by external moisture, oxygen, or the like, the encapsulation layer 400 may protect the display element 310 by covering the display element 310. Referring to FIG. 8, the encapsulation layer 400 may include a first inorganic encapsulation layer 410, an organic encapsulation layer 420, and a second inorganic encapsulation layer 430.

The first inorganic encapsulation layer 410 may cover the opposite electrode 313 and may include silicon oxide (SiO_{X}), silicon nitride (SiN_{X}), and/or silicon oxynitride (SiO_{X}N_{Y}). In an embodiment, other layers including a capping layer may be disposed between the first inorganic encapsulation layer 410 and the opposite electrode 313. Because the first inorganic encapsulation layer 410 is formed along a structure thereunder, an upper surface of the first inorganic encapsulation layer 410 may not be flat as shown in FIG. 8. The organic encapsulation layer 420 may cover the first inorganic encapsulation layer 410 and, unlike the first inorganic encapsulation layer 410, the upper surface of the organic encapsulation layer 420 may be approximately flat. The organic encapsulation layer 420 may include at least one of polyethylene terephthalate, polyethylene naphthalate, polycarbonate, polyimide, polyethylene sulfonate, polyoxymethylene, polyarylate, and hexamethyldisiloxane. The second inorganic encapsulation layer 430 may cover the organic encapsulation layer 420 and may include silicon oxide (SiO_{X}), silicon nitride (SiN_{X}), and/or silicon oxynitride (SiO_{X}N_{Y}).

Because the encapsulation layer 400 includes the first inorganic encapsulation layer 410, the organic encapsulation layer 420, and the second inorganic encapsulation layer 430, even in case that cracks occur inside the encapsulation layer 400, the cracks may not propagate between the first inorganic encapsulation layer 410 and the organic encapsulation layer 420 or between the organic encapsulation layer 420 and the second inorganic encapsulation layer 430 through the above multi-layered structure. With this configuration, forming of a path through which external moisture or oxygen penetrates the inside of a display panel 10 may be prevented or reduced.

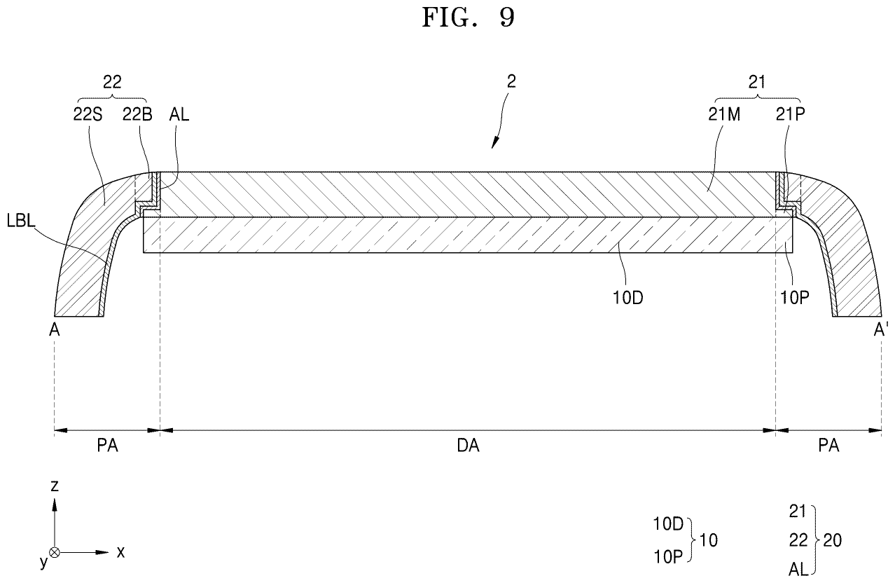

FIG. 9 is a schematic cross-sectional view of a display apparatus 2 according to another embodiment. Because the display apparatus 2 according to an embodiment is similar to the display apparatus 1 described above with reference to FIGS. 1 to 8, differences from the display apparatus 1 described with reference to FIGS. 1 to 8 are described below. In FIG. 9, the same reference numerals as those of FIGS. 1 to 8 denote the same members, and thus, repeated descriptions thereof are omitted.

The display apparatus 1 described with reference to FIGS. 1 to 8 may include the display panel 10 and the cover window 20. The cover window 20 may include the base portion 21, the edge portion 22, and the adhesive layer AL. The base portion 21 may include the main portion 21M and the protrusion 21P, and the edge portion 22 may include the lateral wall portion 22S, and the binding portion 22B. As shown in FIG. 9, according to an embodiment, the display apparatus 2 may include the display panel 10 and the cover window 20. The cover window 20 of the display apparatus 2 may include the base portion 21, the edge portion 22, and the adhesive layer AL. The base portion 21 of the display apparatus 2 may include the main portion 21M and the protrusion 21P, and the edge portion 22 of the display apparatus 2 may include the lateral wall portion 22S, and the binding portion 22B.

In an embodiment, like the transparent base portion 21, the edge portion 22 of the display apparatus 2 may be also transparent. In other words, the edge portion 22 may be light-transmissive. The edge portion 22 may include crystallized glass. Crystallized glass may be specially chemically treated glass, such that fine crystals are precipitated inside the glass by heating amorphous glass to a temperature, for example, 850° C. The strength of the crystallized glass may be improved by this heat treatment. A layer including crystallized glass may have similar strength and scratch resistance to a layer including sapphire. Because manufacturing the cover window using crystallized glass is obvious to those of ordinary skill in the art, detailed description thereof is omitted.

As shown in FIG. 9, at least a portion of the edge portion 22 may be covered by a light-blocking layer LBL. The light-blocking layer LBL may include a light-blocking material. For example, the light-blocking layer LBL may include an opaque material that blocks light. The light-blocking layer LBL may include a black material. The light-blocking material may include at least one of black dye and black particles. In another embodiment, the light-blocking material may include metal particles. The metal particles may be, for example, nickel, aluminum, molybdenum and/or an alloy thereof. In another embodiment, the light-blocking material may include metal oxide particles such as chromium oxide or metal nitride particles such as chromium nitride. For example, the light-blocking material may include at least one of Cr, CrO_{X}, Cr/CrO_{X}, Cr/CrO_{X}/CrN_{Y}, graphite, carbon black, and carbon nanotubes. In another embodiment, the light-blocking material may include black organic pigment, and the black organic pigment may include at least one of aniline black, lactam black, and perylene black.

Accordingly, even in case that the edge portion 22 is transparent, the edge portion 22 at least partially covered by the light-blocking layer LBL may be configured to block light such that the wirings, circuit, or the like of the display panel 10 is not viewed from the outside. It is shown in FIG. 9 that the surfaces of the edge portion 22 adjacent to the display panel 10 are covered by the light-blocking layer LBL. For example, it is shown that a surface of the edge portion 22 corresponding to an inner surface of the cover window 20 in a direction to the display panel 10 is covered by the light-blocking layer LBL, and surfaces of the edge portion 22 adjacent to the adhesive layer AL are covered by the light-blocking layer LBL. However, the disclosure is not limited thereto. For example, a surface of the edge portion 22 corresponding to the outer surface of the cover window 20 in a direction to the display panel 10 may be covered by the light-blocking layer LBL. In another embodiment, only a surface of the edge portion 22 corresponding to the inner surface of the cover window 20 in a direction to the display panel 10 may be covered by the light-blocking layer LBL.

According to an embodiment, the display apparatus with a reduced defect during a manufacturing process may be implemented. However, the scope of the disclosure is not limited by this effect.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a cover window including a base portion, an edge portion protruding from a virtual plane on which the base portion is located at an edge of the base portion, and an adhesive layer coupling the base portion to the edge portion; and
a display panel disposed under the base portion, wherein
the base portion includes a main portion and a protrusion protruding towards the edge portion from the main portion, and
the edge portion includes a lateral wall portion and a binding portion protruding towards the base portion from the lateral wall portion.

2. The display apparatus of claim 1, wherein the base portion includes sapphire.

3. The display apparatus of claim 1, wherein the edge portion includes at least one of black ceramic and black sapphire.

4. The display apparatus of claim 1, wherein the adhesive layer includes a light-blocking material.

5. The display apparatus of claim 1, wherein the binding portion is seated on the protrusion.

6. The display apparatus of claim 5, wherein the protrusion is disposed between the binding portion and a portion of the display panel.

7. The display apparatus of claim 1, wherein a length of the protrusion is in a range of about 0.5 mm to about 1.0 mm.

8. The display apparatus of claim 1, wherein a thickness of the protrusion is less than a thickness of the main portion.

9. The display apparatus of claim 8, wherein the thickness of the protrusion is in a range of about 0.1 mm to about 0.25 mm.

10. The display apparatus of claim 1, wherein
the base portion has a circular shape in a plan view, and
the edge portion has an annular shape in a plan view.

11. A display apparatus comprising:
a cover window including a base portion, an edge portion protruding from a virtual plane on which the base portion is located at an edge of the base portion, and an adhesive layer coupling the base portion to the edge portion;
a display panel disposed under the base portion; and
a light-blocking layer covering at least a portion of the edge portion, wherein
the base portion includes a main portion and a protrusion protruding towards the edge portion from the main portion, and
the edge portion includes a lateral wall portion and a binding portion protruding towards the base portion from the lateral wall portion.

12. The display apparatus of claim 11, wherein the base portion includes sapphire.

13. The display apparatus of claim 11, wherein the edge portion includes crystallized glass.

14. The display apparatus of claim 11, wherein the adhesive layer includes a light-blocking material.

15. The display apparatus of claim 11, wherein the binding portion is seated on the protrusion.

16. The display apparatus of claim 15, wherein the protrusion is disposed between the binding portion and a portion of the display panel.

17. The display apparatus of claim 11, wherein a length of the protrusion is in a range of about 0.5 mm to about 1.0 mm.

18. The display apparatus of claim 11, wherein a thickness of the protrusion is less than a thickness of the main portion.

19. The display apparatus of claim 18, wherein the thickness of the protrusion is in a range of about 0.1 mm to about 0.25 mm.

20. The display apparatus of claim 11, wherein
the base portion has a circular shape in a plan view, and
the edge portion has an annular shape in a plan view.
